(19) United States
(12) Patent Application Publication
(10) Pub. No.: US 2025/0087451 A1
(43) Pub. Date: Mar. 13, 2025

(54) DUAL CATHODE TEMPERATURE-CONTROLLED MULTI-CATHODE ION SOURCE

(71) Applicant: Axcelis Technologies, Inc., Beverly, MA (US)

(72) Inventors: Neil J. Bassom, Hamilton, MA (US); Joshua Abeshaus, Haverhill, MA (US); David Sporleder, Bedford, MA (US)

(21) Appl. No.: 18/820,813

(22) Filed: Aug. 30, 2024

Related U.S. Application Data
(60) Provisional application No. 63/581,160, filed on Sep. 7, 2023.

(51) Int. Cl. H01J 37/30; H01J 37/317

(52) U.S. Cl. CPC H01J 37/3007; H01J 37/3171; H01J 2237/002; H01J 2237/0815; H01J 2237/24585

(57) ABSTRACT

An ion source having a thermionically-emitting cathode coupled to a plasma chamber and is exposed to a plasma chamber environment. A first power supply is coupled to a first filament associated with the thermionically-emitting cathode and is configured to selectively supply a first power to the first filament to heat the first filament to a first temperature and induce a thermionic emission from the thermionically-emitting cathode. A non-thermionically emitting cathode is coupled to the plasma chamber and exposed to the plasma chamber environment. A second power supply supplies a second power to a second filament associated with the non-thermionically emitting cathode and heats the second filament and the non-thermionically emitting cathode to a second temperature while not inducing thermionic emission from the non-thermionically emitting cathode, where condensation within the plasma chamber environment is minimized. A controller can control the first and second power supplies to provide constant power or emission.

### REFERENCE TO RELATED APPLICATIONS

This application claims the benefit of U.S. Provisional Application Ser. No. 63/581,160 filed Sep. 7, 2023, entitled, “DUAL CATHODE TEMPERATURE-CONTROLLED MULTI-CATHODE ION SOURCE”, the contents of all of which are herein incorporated by reference in their entirety.

### TECHNICAL FIELD

The present invention relates generally to ion implantation systems, and more specifically to an improved ion source having multiple cathodes that control a temperature of the ion source to improve a lifetime, stability, and operation of the ion source.

### BACKGROUND

In the manufacture of semiconductor devices, ion implantation is used to dope semiconductors with impurities. Ion implantation systems are often utilized to dope a workpiece, such as a semiconductor wafer, with ions from an ion beam, in order to either produce n- or p-type material doping, or to form passivation layers during fabrication of an integrated circuit. Such beam treatment is often used to selectively implant the wafers with impurities of a specified dopant material, at a predetermined energy level, and in controlled concentration, to produce a semiconductor material during fabrication of an integrated circuit. When used for doping semiconductor wafers, the ion implantation system injects a selected ion species into the workpiece to produce the desired extrinsic material. Implanting ions generated from source materials such as antimony, arsenic, or phosphorus, for example, results in an “n-type” extrinsic material wafer, whereas a “p-type” extrinsic material wafer often results from ions generated with source materials such as boron, gallium, or indium.

A typical ion implanter includes an ion source, an ion extraction device, a mass analysis device, a beam transport device and a wafer processing device. The ion source generates ions of desired atomic or molecular dopant species. These ions are extracted from the source by an extraction system, typically a set of electrodes, which energize and direct the flow of ions from the source, forming an ion beam. Desired ions are separated from the ion beam in a mass analysis device, typically a magnetic dipole performing mass dispersion or separation of the extracted ion beam. The beam transport device, typically a vacuum system containing a series of focusing devices, transports the ion beam to the wafer processing device while maintaining desired properties of the ion beam. Finally, semiconductor wafers are transferred in to and out of the wafer processing device via a wafer handling system, which may include one or more robotic arms, for placing a wafer to be treated in front of the ion beam and removing treated wafers from the ion implanter.

An ion source (commonly referred to as an arc discharge ion source) can include a heated filament cathode for creating ions that are shaped into an appropriate ion beam for wafer treatment. An example of such an ion source is provided in U.S. Pat. No. 5,497,006 to Sferlazzo et al., whereby the ion source has a cathode supported by a base and is positioned with respect to a gas confinement chamber for producing energetic electrons that induce a production of ions in the gas confinement chamber. The cathode of Sferlazzo et al. is a tubular conductive body having an endcap that partially extends into the gas confinement chamber.

### SUMMARY

The present disclosure thus provides systems and apparatuses for increasing the productivity of an ion source in an ion implantation system. Accordingly, the following presents a simplified summary of the disclosure in order to provide a basic understanding of some aspects of the invention. This summary is not an extensive overview of the invention. It is intended to neither identify key or critical elements of the invention nor delineate the scope of the invention. Its purpose is to present some concepts of the invention in a simplified form as a prelude to the more detailed description that is presented later.

In accordance with one example aspect of the disclosure, an ion source is provided, wherein the ion source comprises a plasma chamber defining a plasma chamber environment therein. A thermionically-emitting cathode, also called a primary cathode, is operably coupled to the plasma chamber, whereby at least a first portion of the thermionically-emitting cathode is exposed to the plasma chamber environment. A first filament, for example, is associated with the thermionically-emitting cathode, and a first power supply is electrically coupled to the first filament and configured to selectively supply a first power to the first filament, thereby selectively heating the first filament to a first temperature and inducing a thermionic emission from the thermionically-emitting cathode.

A secondary cathode, for example, is further operably coupled to the plasma chamber, whereby at least a second portion of the secondary cathode is exposed to the plasma chamber environment. A second filament, for example, is associated with the secondary cathode, and a second power supply is electrically coupled to the second filament. The second power supply, for example, is configured to selectively supply a second power to the second filament, thereby selectively heating the second filament to a second temperature and heating the secondary cathode while not inducing thermionic emission from the secondary cathode.

In one example, a controller is provided, wherein the controller has circuitry configured to selectively supply the first power to the first filament and to supply the second power to the second filament, thereby controlling one or more plasma conditions of a plasma within the plasma chamber environment. A feedback apparatus can be further operably coupled to the controller, wherein the control of the first power and the second power are based on a feedback from the feedback apparatus. The feedback apparatus, for example, can comprise one or more of the first power supply and the second power supply, wherein the feedback comprises one or more of a voltage and a current provided by one or more of the first power supply and the second power supply, respectively. The feedback can be further associated with the one or more plasma conditions of the plasma. The feedback apparatus, for example, can comprise a temperature sensor associated with the ion source.

In one example, the secondary cathode is configured to maintain a plasma chamber temperature defined within the plasma chamber to minimize condensation within the plasma chamber.

In another example, the controller can be configured to selectively vary the first power and the second power over a predetermined range, thereby providing a control of an arc current within the plasma chamber that is independent of a total power supplied to the thermionically-emitting cathode and the secondary cathode. The controller can be configured to selectively vary the first power and the second power to provide a substantially constant plasma condition. The substantially constant plasma condition can comprise a maximum arc current when the first power is maximized and the second power is minimized. In another example, the substantially constant plasma condition comprises a minimum arc current when the first power is equal to the second power.

In accordance with another example, an ion source is provided comprising a plasma chamber and both a thermionically-emitting cathode and a secondary cathode operably coupled to the plasma chamber. A power supply is operably coupled to the thermionically-emitting cathode and the secondary cathode and configured to selectively power the thermionically-emitting cathode to form a plasma and to selectively power the secondary cathode concurrent with the formation of the plasma, thereby heating the plasma chamber and minimizing a condensation within the plasma chamber. First and second filaments can be associated with the thermionically-emitting cathode and the secondary cathode, respectively.

The power supply, for example, can be configured to selectively provide a first power to the first filament, wherein the first power heats the first filament to a first temperature and induces thermionic emission from the thermionically-emitting cathode. The power supply can be further configured to provide a second power to the second filament, wherein the second power selectively heats the second filament to a second temperature and heats the secondary cathode while not inducing thermionic emission from the secondary cathode.

According to yet another example, an ion source is provided comprising a plasma chamber, a first thermionically-emitting cathode, and a second thermionically-emitting cathode operably coupled to the plasma chamber. One or more power supplies are respectively operably coupled to the first thermionically-emitting cathode and the second thermionically-emitting cathode, wherein the one or more power supplies are configured to selectively energize the first thermionically-emitting cathode to selectively form a plasma. The one or more power supplies are further configured to selectively energize the second thermionically-emitting cathode concurrent with the formation of the plasma to selectively heat the plasma chamber, whereby condensation within the plasma chamber is minimized.

The one or more power supplies can be configured to supply a first power to the first filament to selectively heat the first filament to a first temperature to induce thermionic emission from the first thermionically-emitting cathode, and the one or more power supplies can be further configured to supply a second power to the second filament to selectively heat the second filament to a second temperature to induce thermionic emission from the second thermionically-emitting cathode, whereby a control of the first power and the second power selectively controls an arc current of the plasma within the plasma chamber over a predetermined range.

A controller can be configured to selectively control an emission current associated with one or more of the first thermionically-emitting cathode and the second thermionically-emitting cathode in a first mode at a constant power. The controller can be further configured to control the first power and the second power associated with the first thermionically-emitting cathode and the second thermionically-emitting cathode in a second mode at a constant emission current.

To the accomplishment of the foregoing and related ends, the disclosure comprises the features hereinafter fully described and particularly pointed out in the claims. The following description and the annexed drawings set forth in detail certain illustrative embodiments of the invention. These embodiments are indicative, however, of a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIGS. 1A-1B illustrate cross-sectional views of example indirectly heated ion sources having one or more indirectly heated cathodes.

FIG. 2 is a block diagram of an ion source in accordance with several example aspects of the present disclosure.

FIG. 3 is a graph illustrating arc current plotted against power provided to a cathode in accordance with various example aspects of the present disclosure.

FIG. 4 is a graph illustrating an example of effects on stability of tuning of a boron ion beam following a formation of phosphorous beam in multiple configurations of the ion source in accordance with various example aspects of the present disclosure.

FIG. 5 is a graph a model of a two-cathode system driven by a constant heating power in accordance with various example aspects of the present disclosure.

FIG. 6 is a schematic view of an example ion implantation system in accordance with various aspects of the present disclosure.

FIG. 7 is a graph of emission current and power for a first thermionically heated cathode in accordance with various aspects of the present disclosure.

FIG. 8 is a graph of emission current and power for a first thermionically heated cathode and a secondary cathode in accordance with various aspects of the present disclosure.

FIG. 9 is a graph of emission current and power for a first thermionically heated cathode and a second thermionically heated cathode in accordance with various aspects of the present disclosure.

FIG. 10 is a graph of emission current and power showing an addressable region for a first thermionically heated cathode and a second thermionically heated cathode in accordance with various aspects of the present disclosure.

### DETAILED DESCRIPTION

The present disclosure is directed generally toward an ion implantation system and an ion source associated therewith. More particularly, the present disclosure provides a configuration of an ion source having a plurality of cathodes to provide a control of a temperature, emission current, and power associated therewith. The present disclosure is directed toward components for said ion implantation system that improve a lifetime, stability, and operation of the ion implantation system.

Accordingly, the present invention will now be described with reference to the drawings, wherein like reference numerals may be used to refer to like elements throughout. It is to be understood that the description of these aspects are merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, elements or other physical or functional units shown in the drawings or described herein could also be implemented by an indirect connection or coupling. Furthermore, it is to be appreciated that functional blocks or units shown in the drawings may be implemented as separate features in one embodiment, and may also or alternatively be fully or partially implemented in a common feature in another embodiment.

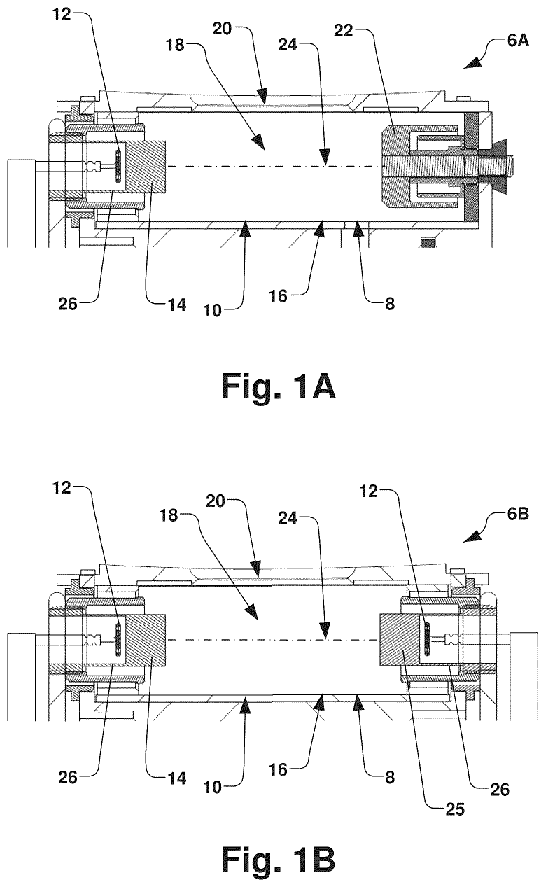

FIG. 1A illustrates a cross section of an ion source 6A used in an ion implantation system. FIG. 1B illustrates a cross section of another ion source 6B used in an ion implantation system. A source material supply 8 provides a source material in a vapor phase to an arc chamber 10. A filament 12 is resistively heated to a temperature at which thermionic emission of electrons occurs. A voltage (a so-called “cathode voltage”) between the filament 12 and a cathode 14 accelerates the emitted electrons from the filament toward the cathode until the cathode, itself, thermally emits electrons. Such an emission scheme is termed in the industry as an indirectly heated cathode (IHC). The cathode 14, for example, serves two purposes; namely, it protects the filament 12 from being bombarded by plasma ions, and it provides electrons for subsequent ionization.

The cathode 14 is biased negatively with respect to an arc chamber 16 in which it resides as a so-called “arc voltage”, and the emitted electrons are accelerated toward a center 18 of the arc chamber. A feed gas (not shown) is flowed into the arc chamber 16, and the emitted electrons subsequently ionize the feed gas, thus forming a plasma (not shown) from which ions can be extracted via an extraction aperture 20 or in the arc chamber. A repeller 22 in FIG. 1A, for example, further charges to the negative floating potential of the plasma and repels electrons back into the plasma, thus increasing the electron mean free path, leading to enhanced ionization and a denser plasma. In FIG. 1B, a second cathode 25 is provided in place of the repeller 22. A magnetic field (not shown) that is parallel to a center axis 24 defined by the cathode 14 and repeller 22 of FIG. 1A or second cathode 25 of FIG. 1B generally confines the emitted and repelled electrons to define a so-called “plasma column”, thus improving ionization and plasma density even further.

An ion source will ultimately fail due to sputtering and punch-through of the cathode 14 if all other failure modes are avoided. Punch-through refers to the case when enough cathode material of the wall 26 has been eroded such that a hole is formed exposing the filament 12 to the plasma. The filament 12 usually fails within a few hours after punch-through. The cathode's useful lifetime can be extended by adding more material to the cathode 14. The amount of material that can be added to the cathode 14, however, is limited by power available to heat the cathode, radiative loses, and the architecture of the ion source, such as of the walls 26 and extraction aperture 20.

The present disclosure appreciates that a multiple-cathode ion source can be advantageous to improve a lifetime of the ion source, whereby one or more secondary cathodes can delay failure of the ion source caused by sputtering eroding a primary cathode. Supplemental heaters positioned around the arc chamber can be further provided in order to operate the ion source at higher temperatures, thereby reducing condensation of material in the arc chamber and allowing faster transitions between ion species. It is also appreciated, however, that changes in power dissipated in the ion source can also lead to scrapped workpieces due to thermal drift in the ion source and extraction system.

The present disclosure, for example, thus provides an independent control of a heating power and an arc current respectively produced by a plurality of cathodes in a multiple cathode ion source, whereby heating power delivered to the multiple cathode ion source is controlled independently of electron current delivered to the plasma by the plurality of cathodes. Accordingly, an arc current and a plasma density can be varied or otherwise controlled while delivering a substantially constant heating power to the multiple cathode ion source. Alternatively, a substantially constant arc current can be maintained while varying the heating power to the plurality of cathodes, whereby the temperature of the multiple cathode ion source can be varied while maintaining a desired output of the multiple cathode ion source.

The present disclosure, for example, further contemplates one or more variable heating power and arc current curves being utilized, as opposed to providing a constant heating power or a constant arc current to the plurality of cathodes. In another example, a first cathode can be solely or primarily configured to control arc current, while a second cathode is primarily configured to maintain a predetermined total heating power.

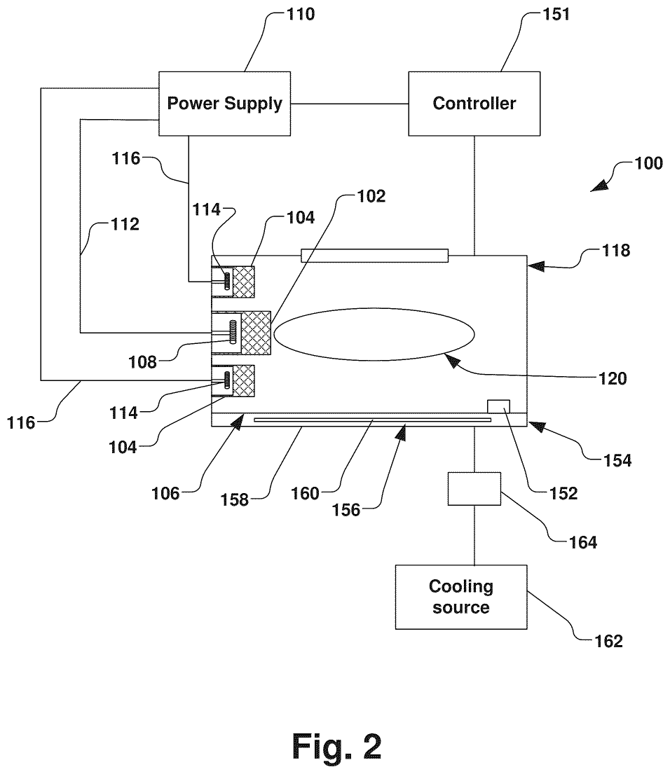

FIG. 2 illustrates an example of an ion source 100 (e.g., a multiple cathode ion source) comprising a first cathode 102 (e.g., a thermionically-emitting cathode, also called a primary cathode) and one or more second cathodes 104 in one example of the present disclosure. It is to be appreciated that the one or more second cathodes (e.g., one or more secondary cathodes) may be configured as thermionically-emitting or non-thermionically-emitting cathodes. For example, the one or more second cathodes 104 can comprise one or more cathodes associated with one or more sidewalls 106 of the ion source 100. Any of the one or more second cathodes 104 of FIG. 2, for example, may be arranged with respect to the ion source 100 in a manner similar to the second cathode 25 of FIG. 1B. The first cathode 102, for example, is positioned in front of a first filament 108, whereby a power supply 110 is configured to selectively apply a first voltage 112 between the first filament and the first cathode in order to direct and accelerate electrons from the first filament to the first cathode, thereby heating the first cathode. One or more of the first cathode 102 and the one or more second cathodes 104, for example, comprises a refractory material.

It is to be appreciated that the first cathode 102 and the one or more second cathodes 104 can have similar or different geometries, and can be constructed of similar or different materials having various emission characteristics associated therewith. For example, the first cathode 102 can be comprised of a first material, and the one or more second cathodes 104 can be comprised of one or more second materials, whereby the first cathode is configured to begin thermionic emission at power that differs from the power to begin thermionic emission of the one or more second cathodes.

The one or more second cathodes 104, for example, can be further positioned in front of one or more second filaments 114, respectively, whereby the power supply 110, for example, can be further configured to selectively apply a second voltage 116 between the respective second filament and second cathode in order to direct and accelerate electrons from the second filament to the second cathode respectively, thus heating the respective second cathode. It is further noted that the power supply 110 can be configured as any number of individual or collective power supplies configured to selectively supply any number of powers, currents, or voltages to any of the first filament 108, the first cathode 102, the one or more second filaments 114, and the one or more second cathodes 104.

When the first cathode reaches a predetermined temperature, electrons are thermionically emitted at an emission current j into a plasma chamber 118 (e.g., an arc chamber), where the electrons collide with gas molecules within the plasma chamber to form a plasma 120. The emission current j from the first cathode 102, for example, is measured as an arc current. While not expressly illustrated, it is to be appreciated that the power supply 110, for example, can be further configured to supply an arc current to any of the first cathode 102, the one or more second cathodes 104, and the plasma chamber 118.

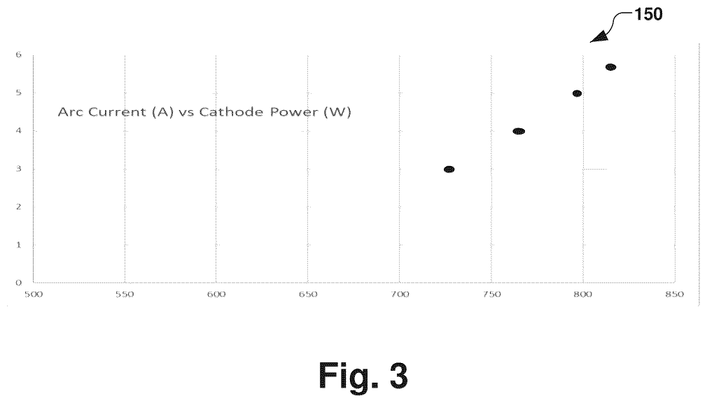

The emission current j from the first cathode is a strong function of temperature T in the form of:

$$j = {AT}^{2} {e}^{\frac{- φ}{kT}} , \qquad ( 1 )$$

where A is a constant associated with fundamental physical constants and an area of the first cathode, k is the Boltzmann constant and Φ is the work function of the first cathode. In one example, the first cathode 102 is comprised of tungsten, whereby thermionic emission from the first cathode occurs at temperatures greater than approximately 2300K. FIG. 3, for example, illustrates a graph 150 of arc current versus power input to the first cathode 102 over a limited range of heating powers. As implied by the graph, for typical cathode geometries and masses, heating powers can be dissipated in the ion source 100 of FIG. 2 by the first cathode 102 with substantially no emission occurring, thus not substantially modifying the plasma 120 within the plasma chamber 118. A controller 151, for example, can be provided to provide a control of the power supply 110 and respective control of current to the first cathode 102 and second cathode 104.

For example, heating power can be dissipated in the ion source 100 for arsenic (As) and boron (B) plasmas for a plurality of purge recipes utilized when changing between the arsenic and boron plasmas for implantation. The plurality of purge recipes, for example, comprise a low-power recipe, a medium-power recipe, and a high-power recipe, whereby a difference in heating power between the highest power and lowest power can be up to several hundred watts.

In another example, each recipe can be run at the highest heating power and at differing emission currents without disturbing the plasma conditions, thereby minimizing or eliminating condensation within the plasma chamber 118 of the ion source 100 of FIG. 2. In one example, feedback for controlling the plasma conditions can be attained directly from power supplies 110 that supply power to each of the first cathode 102 and the second cathode 104 (e.g., voltages and currents reported by power supplies). In another example, closed-loop feedback for controlling the plasma conditions can be attained via a temperature sensor 152 associated with the ion source 100. For example, the temperature sensor 152 can be thermally coupled to, positioned on, or positioned within the plasma chamber 118 and configured to measure a plasma chamber temperature on or within the plasma chamber 118.

The plurality of cathodes, such as the first cathode 102 and one or more second cathodes 104, for example, can comprise one or more thermionically-emitting cathodes and one or more non-thermionically emitting cathodes. For example, the plurality of cathodes can comprise four cathodes, whereby up to three of the cathodes comprise non-thermionically emitting cathodes configured to heat the ion source, thus minimizing condensation.

In another example, the ion source 100 comprises a source body 154 associated with the plasma chamber 118, whereby the source body is thermally stable. For example, the source body 154 comprises the plasma chamber 118 and a cooling apparatus 156 operably coupled to the plasma chamber. The cooling apparatus 156, for example, comprises a cooling plate 158 operably coupled to the plasma chamber 118, wherein the cooling plate comprises one or more cooling channels 160 defined therein. The cooling apparatus 156 further comprises a cooling fluid source 162 in fluid communication with the one or more cooling channels 160 of the cooling plate 158, whereby a pump 164 is configured to pump or flow a cooling fluid (e.g., water) from the cooling fluid source 162 through one or more cooling channels 160 defined within the cooling plate 158. The cooling plate 158, for example, thus provides thermal stability to the plasma chamber 118, whereby the thermally stable source body 154 allows for a lower tolerance in control of the heating power to the one or more second cathodes 104 cathodes.

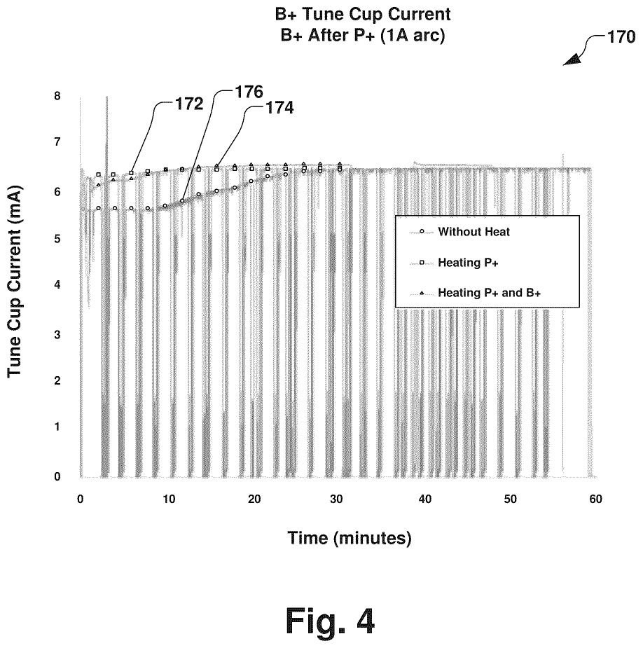

FIG. 4 illustrates a graph 170 of an example showing various effects on stability of tuning of boron (B+) ion beams in an ion source following a formation of phosphorous (P+) ion beams in multiple configurations of the ion source. For example, various tuning cup current measurements are illustrated during tuning of various boron ion beams subsequent to the formation of phosphorous ion beams in an ion source having a first configuration and a second configuration. In the first configuration of the ion source, a first cathode comprising a thermionically-emitting cathode and a second cathode comprising a non-thermionically emitting cathode are provided, whereby both the first cathode and the second cathode are powered during formation of the phosphorus ion beam, thereby supplementally heating the ion source in the manner discussed above. In the second configuration of the ion source, the second cathode is not powered during formation of the phosphorus ion beam, thus providing no supplemental heat to the ion source during the formation of the phosphorus ion beam.

First tune cup measurements 172 and second tune cup measurements 174 illustrate currents measured at a tuning cup during tuning of the ion source in the first configuration. A third tune cup measurement 176 illustrates the current measured at the tuning cup during tuning of the ion source in the second configuration. The first and second tune cup measurements 172, 174, for example, clearly illustrate a higher stability of the tuning currents when the second cathode is powered in the second configuration, whereas the third tune cup measurement 176 illustrates greater instability without powering of the second cathode, whereby no supplemental heating is provided.

The present disclosure further appreciates that electron emission is a strongly non-linear function of the heating power delivered to the cathode (e.g., and heating power delivered to the ion source). As such, varying the arc current while maintaining a constant heating power can be accomplished by varying or otherwise controlling a proportion of heating supplied to each of the cathodes in a multi-cathode arrangement, as described above.

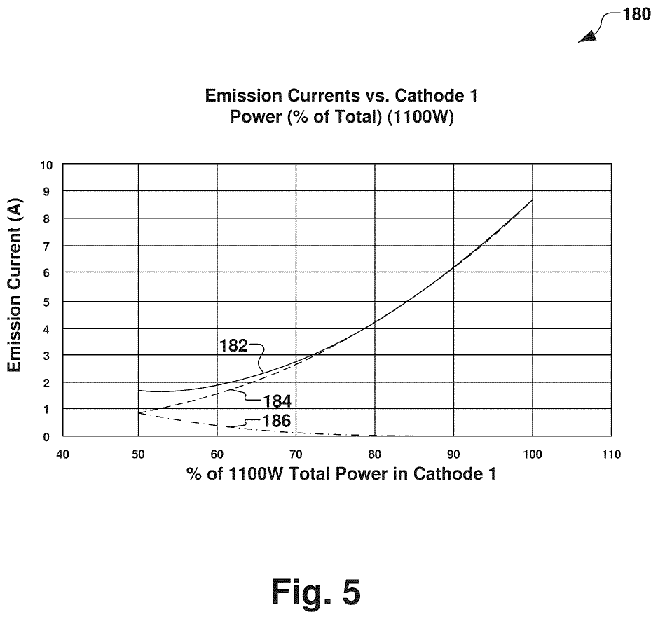

FIG. 5, for example, illustrates a graph 180 of a model of a two-cathode system driven by a constant 1100 W of heating power. Accordingly, a total electron emission current 182 (e.g., equal to the arc current) in the model shown in FIG. 5 can be varied between approximately 1.5 A and 8.5 A to provide constant total power by shifting or otherwise controlling the division of power between the thermionically-emitting cathode and non-thermionically emitting cathode(s). For example, a maximum arc current can be achieved when all power is delivered to a single cathode (illustrated by line 184), while a minimum arc current can be achieved when the power is divided equally between the thermionically-emitting cathode and non-thermionically emitting cathode(s) (illustrated by line 186).

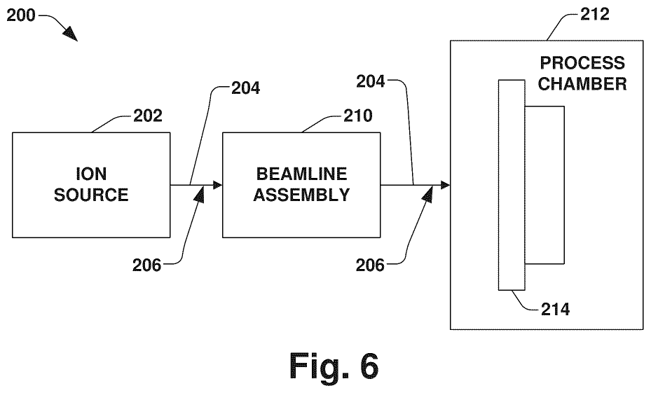

One or more systems, apparatuses, and/or methods of the present disclosure, for example, can be practiced or otherwise implemented in associated with an ion implantation system. FIG. 6, for example, illustrates an ion implantation system 200 that includes an ion source 202 for producing an ion beam 204 along a beam path 206. A beamline assembly 210 is provided downstream of the ion source 202 to receive a beam therefrom. The beamline assembly 210 may include (not shown) a mass analyzer, an acceleration structure, which may include, for example, one or more gaps, and an angular energy filter. The mass analyzer includes a field generating component, such as a magnet, and operates to provide a field across the beam path 206 so as to deflect ions from the ion beam 204 at varying trajectories according to mass (e.g., mass-to-charge ratio). Ions traveling through the magnetic field experience a force which directs individual ions of a desired mass along the beam path 206 and which deflects ions of undesired mass away from the beam path.

A process chamber 212 is provided in the ion implantation system 200, which contains a target location that receives the ion beam 204 from the beamline assembly 210 and supports one or more workpieces 214 such as semiconductor wafers along the beam path 206 for implantation using the final mass analyzed ion beam. The process chamber 212 then receives the ion beam 204 which is directed toward a workpiece 214.

The ion source 202, for example, generates the ion beam 204 by ionizing a source material (e.g., a source gas) containing a desired dopant element within the ion source. The ionized source gas is subsequently extracted from the ion source 202 in the form of the ion beam 204.

The present disclosure appreciates that emission from a thermionic cathode is a substantially non-linear function of temperature, as provided in equation (1), above. The temperature of the thermionic cathode is also a substantially non-linear function of the power supplied to the cathode, and is based on a complex function reflecting the relative degree of conduction and radiation losses. However, the present disclosure appreciates that radiation dominates at the temperatures at which emission takes place, and as such, an assumption of T∝P^{0.25} is acceptable, thus implying that the emission current j would vary as:

$$j = {P}^{0.5} exp ( - ϕ / {kP}^{0.25} ) . \qquad ( 2 )$$

While the exact form of the emission current/power curve is not substantially consequential, the present disclosure appreciates that the relationship between emission current and power being non-linear is substantially consequential.

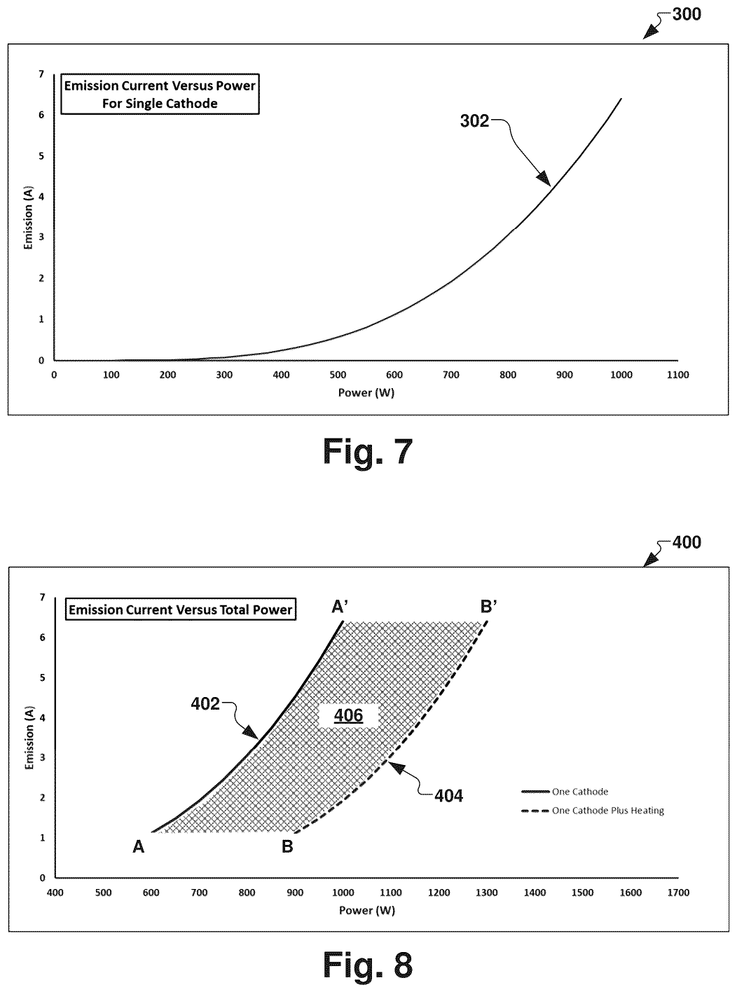

For example, under the above crude assumptions, and using typical dimensions for tungsten cathodes used in an IHC, a graph 300 is shown in FIG. 7, whereby a curve 302 is illustrated showing emission current versus power. The emission current from the cathode, for example, determines the arc current in the ion source. However, the emission current and the arc current are not generally equal. Higher emission currents, for example, lead to denser plasmas and higher beam currents. For example, the arc current can be set for a given process recipe, whereby the arc current is further used as a feedback signal to control the cathode power.

For a single cathode operating under given source parameters, for example, the arc current, and hence the emission current, determines the power which is to be supplied to the ion source, and therefore generally determines the temperature of the ion source (e.g., not only the cathode).

The present disclosure appreciates that for some species (e.g., carbon), it can be advantageous to operate the ion source at a high temperature in order to prevent or otherwise ameliorate the formation of deposits, even though other more desirable plasma conditions may call for lower arc currents, cathode powers, and ion source temperatures. In other circumstances, changes in the temperature of the ion source, such as may be caused by transitioning between various ion beams require differing plasma conditions and power levels, can lead to mechanical movements in the ion source, thus causing long transition times between the various ion beams. One approach to decouple source power and temperature from arc current, for example, is to supply auxiliary heat via external heaters that can be located on the sides of the plasma chamber.

In some examples, the present disclosure contemplates an ion source having two cathodes (e.g., first and second cathodes), wherein the second cathode is provided in place of a conventional repeller that is typically located opposite the first cathode along the axis of the plasma chamber and aligned with the applied magnetic field. One motivation for providing two cathodes, for example, is to allow switching between the two cathodes, whereby erosion caused by sputtering by ions from the plasma can be switched from one to the other, thus prolonging a lifetime of the ion source when erosion of the cathode(s) is the primary failure mechanism of the ion source. For ribbon-based implanters, for example, emission from both cathodes (e.g., including different degrees of emission from the respective first and second cathodes) can produce a more uniform emission of ions along the length of the ion source.

The present disclosure thus appreciates that the provision of the second cathode, for example, allows for a decoupling of arc current and source power without providing external heaters. As illustrated by the curve 302, for example, a cathode supplied with less than approximately 300 W of power does not emit an appreciable amount of electrons. As such, the present disclosure contemplates advantageously powering the second cathode and injecting up to 300 W of extra power into the ion source without deleteriously altering plasma conditions.

The disclosure thus provides additional flexibility in the setup and operation of the ion source, as illustrated in graph 400 shown in FIG. 8. Without heating, for example, there is no decoupling of arc current and power, and the ion source can only be operated along a first curve 402 (e.g., line A-A′). A provision of a second cathode (e.g., a non-emitting cathode), for example, defines a second curve 404 (e.g., line B-B′). As such, the ion source can now be operated anywhere within a first region 406 between the first and second curves 402, 404 (e.g., the shaded region between A-A′-B′-B).

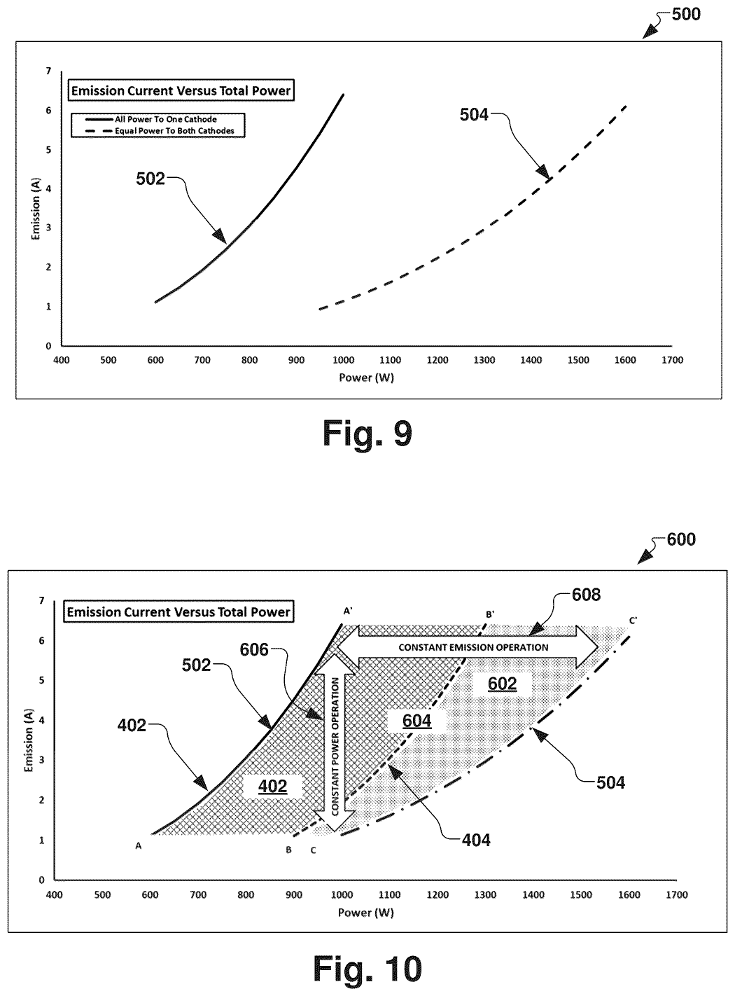

The present disclosure contemplates a further improvement in power by advantageously driving the second cathode into emission. Since the emission current is a supra-linear function of power, halving the emission current cuts the power by less than half. Thus, if two cathodes each supply half of the emission current, the source power is further increased. FIG. 9, for example, illustrates a graph 500 showing a first emission current/source power curve 502 for a single cathode (e.g., aligning with the first curve 402 also shown in FIG. 8), and a second emission current/source power curve 504 for two cathodes with each of the two cathodes supplying half the current.

The present disclosure, for example, contemplates that by controlling the fraction of emission current supplied by each of at least two cathodes, an emission current/source power can be advantageously controlled in a selective manner to provide a wide range of powers within a region between the first and second emission current/source power curves 502, 504. For example, as illustrated in FIG. 10, a graph 600 is provided showing the first region 406 and a second region 602 (e.g., the shaded region between B-B′-C′-C). Accordingly, an extended addressable region 604 (e.g., the shaded region between A-A′-C′-C) is thus defined, where it can be seen that the extended addressable region is larger than the first region 406, alone.

As illustrated in FIG. 10, a vertical arrow 606, for example, represents a constant power mode of operation (e.g., a first mode), whereby the emission current can be controlled in the present example between 1 and 6 amps while maintaining a constant source power and temperature. The constant power mode of operation, for example, can be advantageous for improving transition times. A horizontal arrow 608, for example, represents a constant emission current mode of operation (e.g., a second mode) over a wide range of powers, that can be advantageous for operating at hotter process recipes. For example, by dividing the emission current between the two cathodes, additional process flexibility is provided in terms of arc current/source power parameters. It is noted that, for simplicity, FIGS. 8-10 illustrate an example where the at least two cathodes are substantially identical. However, it is to be appreciated that the at least two cathodes may differ in structural geometry and/or material composition thereof.

It is noted that an assumption that plasma conditions are unchanged when shifting the emission current between first and second cathodes is reliant upon the first and second cathodes being positioned at opposing ends of the ion source chamber, such as illustrated in FIG. 1B (e.g. the second cathode is positioned opposing the first cathode along a cathode/repeller axis defined in a single cathode ion source). Such an assumption, for example, may not hold for cathodes located along the side of the ion source. Although side cathodes would emit electrons, they may not couple efficiently into the plasma, whereby shifts in cathode powers, for example, can change the plasma.

Although the invention has been shown and described with respect to a certain embodiment or embodiments, it should be noted that the above-described embodiments serve only as examples for implementations of some embodiments of the present invention, and the application of the present invention is not restricted to these embodiments. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more other features of the other embodiments as may be desired and advantageous for any given or particular application. Accordingly, the present invention is not to be limited to the above-described embodiments, but is intended to be limited only by the appended claims and equivalents thereof.

1. An ion source comprising:
a plasma chamber defining a plasma chamber environment therein;
a thermionically-emitting cathode operably coupled to the plasma chamber, whereby at least a first portion of the thermionically-emitting cathode is exposed to the plasma chamber environment;
a first filament associated with the thermionically-emitting cathode;
a first power supply electrically coupled to the first filament and configured to selectively supply a first power to the first filament, thereby selectively heating the first filament to a first temperature and inducing a thermionic emission from the thermionically-emitting cathode;
a non-thermionically emitting cathode operably coupled to the plasma chamber, whereby at least a second portion of the non-thermionically emitting cathode is exposed to the plasma chamber environment;
a second filament associated with the non-thermionically emitting cathode; and
a second power supply electrically coupled to the second filament and configured to selectively supply a second power to the second filament, thereby selectively heating the second filament to a second temperature and heating the non-thermionically emitting cathode while not inducing thermionic emission from the non-thermionically emitting cathode.

2. The ion source of claim 1, further comprising a controller having circuitry configured to selectively supply the first power to the first filament and to selectively supply the second power to the second filament, thereby controlling one or more plasma conditions of a plasma within the plasma chamber environment.

3. The ion source of claim 2, further comprising a feedback apparatus operably coupled to the controller, wherein the first power and the second power are based on a feedback from the feedback apparatus.

4. The ion source of claim 3, wherein the feedback apparatus comprises one or more of the first power supply and the second power supply, wherein the feedback comprises one or more of a voltage and a current provided by one or more of the first power supply and the second power supply, respectively.

5. The ion source of claim 4, wherein the feedback is further associated with the one or more plasma conditions of the plasma.

6. The ion source of claim 3, wherein the feedback apparatus comprises a temperature sensor associated with the ion source.

7. The ion source of claim 6, wherein the temperature sensor is configured to measure a plasma chamber temperature on or within the plasma chamber.

8. The ion source of claim 1, further comprising a source body associated with the plasma chamber, wherein the source body comprises a cooling apparatus operably coupled to the plasma chamber and configured to selectively cool the plasma chamber.

9. The ion source of claim 8, wherein the cooling apparatus comprises:
a cooling plate operably coupled to the plasma chamber, wherein the cooling plate comprises one or more cooling channels defined therein;
a cooling fluid source in fluid communication with the one or more cooling channels; and
a pump configured to pump a cooling fluid from the cooling fluid source through the one or more cooling channels.

10. The ion source of claim 1, comprising:
a plurality of non-thermionically emitting cathodes operably coupled to the plasma chamber; and
a plurality of second filaments respectively associated with the plurality of non-thermionically emitting cathodes, and wherein the second power supply is electrically coupled to the plurality of second filaments.

11. The ion source of claim 1, wherein the thermionically-emitting cathode and the non-thermionically emitting cathode are similarly dimensioned.

12. The ion source of claim 1, further comprising a repeller positioned generally opposite the thermionically-emitting cathode within the plasma chamber.

13. The ion source of claim 12, wherein the non-thermionically emitting cathode is further positioned generally opposite to the repeller within the plasma chamber.

14. The ion source of claim 1, wherein one or more of the thermionically-emitting cathode and non-thermionically-emitting cathode comprises a refractory material.

15. The ion source of claim 1, wherein the non-thermionically emitting cathode is configured to maintain a plasma chamber temperature defined within the plasma chamber to minimize condensation within the plasma chamber.

16. The ion source of claim 1, further comprising a controller configured to selectively vary the first power and the second power over a predetermined range, thereby providing an independent control of an arc current and a power within the plasma chamber.

17. The ion source of claim 16, wherein the controller is configured to selectively vary the first power and the second power to provide a substantially constant plasma condition.

18. The ion source of claim 17, wherein the substantially constant plasma condition comprises a maximum arc current when the first power is maximized and the second power is minimized.

19. The ion source of claim 18, wherein the substantially constant plasma condition comprises a minimum arc current when the first power is equal to the second power.

20. An ion source comprising:
a plasma chamber;
a thermionically-emitting cathode operably coupled to the plasma chamber;
a non-thermionically-emitting cathode operably coupled to the plasma chamber; and
a power supply operably coupled to the thermionically-emitting cathode and non-thermionically-emitting cathode and configured to selectively power the thermionically-emitting cathode to form a plasma and to selectively power the non-thermionically-emitting cathode concurrent with the formation of the plasma, thereby heating the plasma chamber and minimizing a condensation within the plasma chamber.

21. The ion source of claim 20, further comprising:
a first filament associated with the thermionically-emitting cathode, wherein the power supply is electrically coupled to the first filament; and
a second filament associated with the non-thermionically-emitting cathode, wherein the power supply is electrically coupled to the second filament.

22. The ion source of claim 21, wherein the power supply is configured to selectively provide a first power to the first filament, wherein the first power heats the first filament to a first temperature and induces thermionic emission from the thermionically-emitting cathode, and wherein the power supply is further configured to provide a second power to the second filament, wherein the second power selectively heats the second filament to a second temperature and heats the non-thermionically-emitting cathode while not inducing thermionic emission from the non-thermionically-emitting cathode.

23. An ion source comprising:
a plasma chamber;
a first thermionically-emitting cathode operably coupled to the plasma chamber;
a second thermionically-emitting cathode operably coupled to the plasma chamber; and
one or more power supplies respectively operably coupled to the first thermionically-emitting cathode and the second thermionically-emitting cathode, wherein the one or more power supplies are configured to selectively energize the first thermionically-emitting cathode to selectively form a plasma, and wherein the one or more power supplies are further configured to selectively energize the second thermionically-emitting cathode concurrent with the formation of the plasma to selectively heat the plasma chamber, whereby condensation within the plasma chamber is minimized.

24. The ion source of claim 23, further comprising:
a first filament electrically coupled to the one or more power supplies, wherein the first filament is associated with the first thermionically-emitting cathode; and
a second filament electrically coupled to the one or more power supplies, wherein the second filament is associated with the second thermionically-emitting cathode.

25. The ion source of claim 24, wherein the one or more power supplies are configured to supply a first power to the first filament to selectively heat the first filament to a first temperature to induce thermionic emission from the first thermionically-emitting cathode, and wherein the one or more power supplies are further configured to supply a second power to the second filament to selectively heat the second filament to a second temperature, to induce thermionic emission from the second thermionically-emitting cathode, whereby a control of the first power and the second power selectively controls an arc current of the plasma within the plasma chamber over a predetermined range.

26. The ion source of claim 25, further comprising a controller configured to selectively control an emission current associated with one or more of the first thermionically-emitting cathode and the second thermionically-emitting cathode in a first mode at a constant power, and wherein the controller is configured to control the first power and the second power associated with the first thermionically-emitting cathode and the second thermionically-emitting cathode in a second mode at a constant emission current.
